(19) United States
(12) Patent Application Publication
(10) Pub. No.: US 2017/0346043 A1
(43) Pub. Date: Nov. 30, 2017

(54) ORGANIC LIGHT EMITTING DIODE DISPLAY

(71) Applicant: SAMSUNG DISPLAY CO., LTD., Yongin-si (KR)

(72) Inventors: Duk Jin LEE, Suwon-si (KR); Woo Suk JUNG, Cheonan-Si (KR); Tae Eun KIM, Busan (KR); Ji Eun PARK, Busan (KR)

(21) Appl. No.: 15/675,588

(22) Filed: Aug. 11, 2017

Related U.S. Application Data
(62) Division of application No. 14/855,086, filed on Sep. 15, 2015.

(30) Foreign Application Priority Data
Feb. 2, 2015 (KR) 10-2015-0016360

(51) Int. Cl. H01L 51/52; H01L 27/32

(52) U.S. Cl. CPC H01L 51/5275; H01L 27/322; H01L 2251/558; H01L 51/524

(57) ABSTRACT

An organic light emitting diode display including: a plurality of pixels on a substrate; an encapsulation substrate facing the substrate; a color filter on one surface of the encapsulation substrate facing the substrate and including a red filter, a green filter, and a blue filter; and an overcoat layer including a first region covering the red filter, a second region covering the green filter, and a third region covering the blue filter. At least one of the first region, the second region, and the third region has an optimized refractive index and/or an optimized thickness.

### CROSS-REFERENCE TO RELATED APPLICATION(S)

This application is a divisional of U.S. patent application Ser. No. 14/855,086, filed Sep. 15, 2015, which claims priority to and the benefit of Korean Patent Application No. 10-2015-0016360, filed Feb. 2, 2015, the entire contents of both of which are incorporated herein by reference.

### BACKGROUND

The described technology relates generally to an organic light emitting diode display.

### DESCRIPTION OF THE RELATED ART

A typical organic light emitting diode display includes a polarization film including a linear polarizing plate and a ¼ wavelength plate to suppress external light reflection. A component of the incident external light that vibrates in a parallel direction with a transmissive axis of the linear polarizing plate is transmitted through the linear polarizing plate, and the transmitted component is converted into a circular polarizing plate rotating in one direction while passing through the ¼ wavelength plate.

The circular polarization becomes a circular polarization rotating in an opposite direction while being reflected by a metal layer of an organic light emitting diode, and the circular polarization is converted into a linear polarization while passing through the ¼ wavelength plate. A vibration direction of the linear polarization is orthogonal to the transmissive axis of the linear polarizing plate and therefore it is not transmitted through the linear polarizing plate. A polarization film minimizes or reduces the external reflection based on the above principle and increases outdoor visibility.

However, since the polarization film has a considerable thickness, it is difficult to make the organic light emitting diode display thin, and about half of the external light and light emitted from the organic light emitting diode is absorbed by the linear polarizing plate, and therefore light efficiency deteriorates. Therefore, as a technology of replacing the polarization film, a technology of forming a color filter has been proposed. The color filter includes a red filter, a green filter, and a blue filter which correspond to a red pixel, a green pixel, and a blue pixel, respectively.

The color filter is formed on one surface of an encapsulation substrate facing the organic light emitting diode. However, since an air gap is present between the organic light emitting diode and the color filter, some of the light emitted from the organic light emitting diode may be reflected from a surface of the color filter due to a difference between a refractive index of air and a refractive index of the color filter. Therefore, transmittance of the light emitted from the organic light emitting diode is reduced, and therefore the light efficiency of the organic light emitting diode display deteriorates.

The above information disclosed in this Background section is only for enhancement of understanding of the background of the described technology and therefore it may contain information that does not form prior art.

### SUMMARY

The described technology has been made in an effort to provide an organic light emitting diode display capable of improving or maximizing light efficiency by reducing or minimizing a transmittance loss due to a color filter, in the organic light emitting diode display including the color filter.

An exemplary embodiment provides an organic light emitting diode display including: a plurality of pixels on a substrate; an encapsulation substrate facing the substrate; a color filter on one surface of the encapsulation substrate facing the substrate and including a red filter, a green filter, and a blue filter; and an overcoat layer including a first region covering the red filter, a second region covering the green filter, and a third region covering the blue filter. At least one of the first region, the second region, and the third region may satisfy at least one of the following Condition 1 and Condition 2

$$\begin{matrix}OC ( n ) = \sqrt{CF ( n ) \times AIR ( n )} & Condition 1 \\ OC ( d ) = \frac{λ}{4 \sqrt{CF ( n ) \times AIR ( n )}} & Condition 2\end{matrix}$$

In the above Conditions 1 and 2, OC(n) may represent a refractive index of the corresponding region, CF(n) may represent a refractive index of the corresponding color filter, AIR(n) may represent a refractive index of air, OC(d) may represent a thickness of the corresponding region, and λ may represent a peak wavelength of the corresponding pixel.

The plurality of pixels may include a red pixel, a green pixel, and a blue pixel and the red filter, the green filter, and the blue filter may be respectively positioned to correspond to the red pixel, the green pixel, and the blue pixel.

The red pixel, the green pixel, and the blue pixel may have peak wavelength of λ1, λ2, and λ3, respectively. The refractive index CF(n) of the color filter may be any one of the refractive index of the red filter which is measured in the wavelength of λ1, the refractive index of the green filter which is measured in the wavelength of λ2, and the refractive index of the blue filter which is measured in the wavelength of λ3.

The refractive index of the overcoat layer may be larger than that of air and may be smaller than that of the color filter. The refractive index of the overcoat layer may be between 1.2 and 1.3 and may be made of acrylic resin which includes LiF.

Any one of the first region, the second region, and the third region may satisfy the above Conditions 1 and 2 and the remaining two of the regions may be made of the same material as any one of the above regions and may have the same thickness as any one of the above regions.

Any one of the first region, the second region, and the third region may satisfy the above Condition 1 and the remaining two of the regions may be made of the same material as any one of the above regions. All of the first region, the second region, and the third region may satisfy the above Condition 2.

Any one of the first region, the second region, and the third region may satisfy the above Condition 1 and the remaining two of the regions may be made of the same material as any one of the above regions. Two of the first region, the second region, and the third region may satisfy the above Condition 2 and the remaining one of the regions may have the same thickness as any one of the two regions.

All of the first region, the second region, and the third region may satisfy the above Conditions 1 and 2.

Two regions of the first region, the second region, and the third region may satisfy the above Condition 1 and the remaining one of the regions may be made of the same material as any one of the two regions. Any one of the first region, the second region, and the third region may satisfy the above Condition 2 and the remaining two of the regions may have the same thickness as any one of the above regions.

All of the first region, the second region, and the third region may satisfy the above Condition 1. Any one of the first region, the second region, and the third region may satisfy the above Condition 2 and the remaining two of the regions have the same thickness as any one of the above regions.

Another exemplary embodiment provides an organic light emitting diode display including: a plurality of pixels on a substrate; an encapsulation substrate facing the substrate; a color filter on one surface of the encapsulation substrate facing the substrate and including a red filter, a green filter, and a blue filter; and an overcoat layer including a first region covering the red filter, a second region covering the green filter, and a third region covering the blue filter. At least two of the first region, the second region, and the third region may be different from each other with respect to at least one of a refractive index and a thickness.

At least one of the first region, the second region, and the third region may satisfy the following Condition 1.

OC(n)=\sqrt{CF(n)×AIR(n)} 1

In the above Condition 1, OC(n) may represent a refractive index of the corresponding region, CF(n) may represent a refractive index of the corresponding color filter, and AIR(n) may represent a refractive index of air.

At least one of the first region, the second region, and the third region may satisfy the following Condition 2.

$$OC ( d ) = \frac{λ}{4 \sqrt{CF ( n ) \times AIR ( n )}} \qquad 2$$

In the above Condition 2, OC(d) may represent a thickness of the corresponding region, λ may represent a peak wavelength of the corresponding pixel, CF(n) may represent a refractive index of the corresponding color filter, and AIR(n) may represent a refractive index of air.

According to an exemplary embodiment, the overcoat layer makes the change in the refractive index smooth when the light emitted from the organic light emitting diode is incident on the color filter, thereby reducing the amount of light reflected from the surface of the color filter. Therefore, according to the organic light emitting diode display according to an exemplary embodiment, it is possible to improve or maximize the light efficiency by reducing the transmittance loss due to the color filter and optimizing the refractive index and the thickness of the overcoat layer in at least one pixel.

### BRIEF DESCRIPTION OF THE DRAWINGS

FIG. 1 is a cross-sectional view of an organic light emitting diode display according to a first exemplary embodiment.

FIG. 2 is an equivalent diagram of one pixel in the organic light emitting diode display illustrated in FIG. 1.

FIG. 3 is a graph illustrating emission spectra of a red pixel, a green pixel, and a blue pixel in the organic light emitting diode display illustrated in FIG. 1.

FIG. 4 is a graph illustrating refractive indexes depending on wavelengths of a red filter, a green filter, and a blue filter in the organic light emitting diode display illustrated in FIG. 1.

FIG. 5 is a cross-sectional view of an organic light emitting diode display according to a second exemplary embodiment.

FIG. 6 is a cross-sectional view of an organic light emitting diode display according to a third exemplary embodiment.

FIG. 7 is a cross-sectional view of an organic light emitting diode display according to a fourth exemplary embodiment.

FIG. 8 is a cross-sectional view of an organic light emitting diode display according to a fifth exemplary embodiment.

FIG. 9 is a cross-sectional view of an organic light emitting diode display according to a sixth exemplary embodiment.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

The terminology used herein is for the purpose of describing particular embodiments only and is not intended to be limiting of the present invention. As used herein, the singular forms “a” and “an” are intended to include the plural forms as well, unless the context clearly indicates otherwise.

Throughout the present specification, it will be understood that when an element such as a layer, film, region, or substrate is referred to as being “on” another element, it can be directly on the other element or intervening elements (or components) may also be present. Further, in the specification, the word “on” means positioning on or below the object portion, but does not essentially mean positioning on the upper side of the object portion based on a gravity direction.

It will be understood that, although the terms “first”, “second”, “third”, etc., may be used herein to describe various conditions, equations, elements, components, regions, layers, and/or sections, these conditions, equations, elements, components, regions, layers and/or sections should not be limited by these terms. These terms are only used to distinguish one condition, equation, element, component, region, layer or section from another condition, element, component, region, layer or section. Thus, a first condition, equation, element, component, region, layer, or section discussed below could be termed a second condition, equation, element, component, region, layer, or section, without departing from the spirit and scope of the present invention.

As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the present invention refers to “one or more embodiments of the present invention.” Also, the term “exemplary” is intended to refer to an example or illustration.

It will be understood that when an element or layer is referred to as being “on,” “connected to,” “coupled to,” “connected with,” “coupled with,” or “adjacent to” another element or layer, it can be “directly on,” “directly connected to,” “directly coupled to,” “directly connected with,” “directly coupled with,” or “directly adjacent to” the other element or layer, or one or more intervening elements or layers may be present. When an element or layer is referred to as being “directly on,” “directly connected to,” “directly coupled to,” “directly connected with,” “directly coupled with,” or “immediately adjacent to” another element or layer, there are no intervening elements or layers present.

As used herein, the term “substantially,” “about,” and similar terms are used as terms of approximation and not as terms of degree, and are intended to account for the inherent deviations in measured or calculated values that would be recognized by those of ordinary skill in the art.

As used herein, the terms “use,” “using,” and “used” may be considered synonymous with the terms “utilize,” “utilizing,” and “utilized,” respectively.

In addition, unless explicitly described to the contrary, the words “include” and “comprise” and variations such as “includes,” “including,” “comprises,” or “comprising”, will be understood to imply the inclusion of stated elements (or components) but not the exclusion of any other elements (or components). In addition, the size and thickness of each configuration shown in the drawings are arbitrarily shown for understanding and ease of description, but the present disclosure is not limited thereto.

Further, it will also be understood that when one element, component, region, layer and/or section is referred to as being “between” two elements, components, regions, layers, and/or sections, it can be the only element, component, region, layer and/or section between the two elements, components, regions, layers, and/or sections, or one or more intervening elements, components, regions, layers, and/or sections may also be present.

Also, any numerical range recited herein is intended to include all sub-ranges of the same numerical precision subsumed within the recited range. For example, a range of “1.0 to 10.0” or between “1.0 and 10.0” are intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include ail higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112, first paragraph, and 35 U.S.C. §132(a).

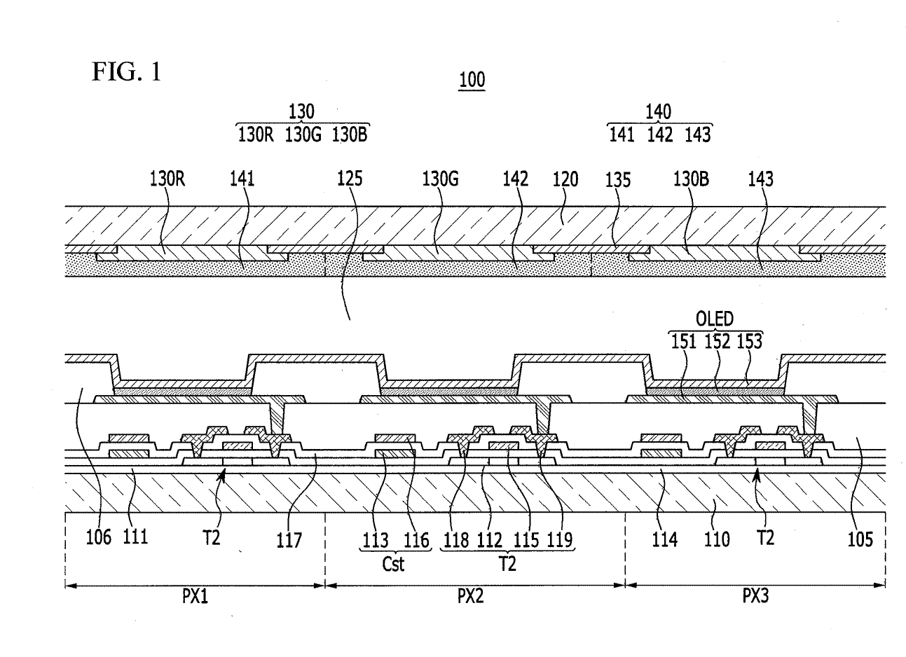

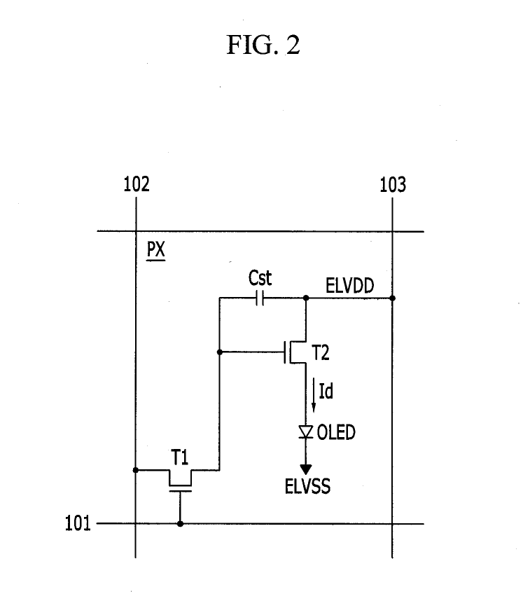

FIG. 1 is a cross-sectional view of an organic light emitting diode display according to a first exemplary embodiment, and FIG. 2 is an equivalent diagram of one pixel in the organic light emitting diode display illustrated in FIG. 1.

Referring to FIGS. 1 and 2, an organic light emitting diode display 100 includes a substrate 110, a plurality of pixels PX1, PX2, and PX3 formed on the substrate 110, an encapsulation substrate 120 bonded to the substrate 110 to encapsulate the plurality of pixels PX1, PX2, and PX3, a color filter 130 formed on one surface of the encapsulation substrate 120 toward (e.g., facing) the substrate 110, and an overcoat layer 140.

A display area of the substrate 110 is provided with a plurality of signal lines 101, 102, and 103 and the plurality of pixels PX1, PX2, and PX3 which are connected to the plurality of signal lines 101, 102, and 103 and are arranged in approximately (e.g., substantially) a matrix form. The plurality of signal lines 101, 102, and 103 includes a scan line 101 through which a scan signal is transferred, a data line 102 through which a data signal is transferred, and a driving voltage line 103 through which a driving voltage (ELVDD) is transferred.

The scan line 101 is substantially in parallel with a row direction and the data line 102 and the driving voltage line 103 are substantially in parallel with a column direction. Each pixel PX includes a switching thin film transistor T1, a driving thin film transistor T2, a storage capacitor Cst, and an organic light emitting diode (OLED).

The switching thin film transistor T1 includes a control terminal, an input terminal, and an output terminal. The control terminal is connected to the scan line 101, the input terminal is connected to the data line 102, and the output terminal is connected to the driving thin film transistor T2. The switching thin film transistor T1 transfers the data signal applied to the data line 102 to the driving thin film transistor T2 in response to the scan signal applied to the scan line 101.

The driving thin film transistor T2 also includes a control terminal, an input terminal, and an output terminal. The control terminal is connected to the switching thin film transistor T1, the input terminal is connected to the driving voltage line 103, and the output terminal is connected to the organic light emitting diode (OLED). The driving thin film transistor T2 transfers an output current Id of which a magnitude varies depending on a voltage applied between the control terminal and the input terminal.

The storage capacitor Cst is connected between the control terminal and the input terminal of the driving thin film transistor T2. The storage capacitor Cst charges the data signal applied to the control terminal of the driving thin film transistor T2 and maintains the charged data signal even after the switching thin film transistor T1 is turned off.

The organic light emitting diode (OLED) includes a pixel electrode 151 connected to the output terminal of the driving thin film transistor T2, a common electrode 153 connected to a common voltage (ELVSS), and an emission layer 152 positioned between the pixel electrode 151 and the common electrode 153. The organic light emitting diode (OLED) emits light of which the intensity varies depending on the output current of the driving thin film transistor T2.

A pixel configuration of the organic light emitting diode display 100 is not limited to the foregoing example and if necessary, a separate thin film transistor and a separate capacitor may be added thereto.

A buffer layer 111 is formed on the substrate 110. The substrate 110 may be an insulating substrate which is made of insulating materials such as glass, quartz, ceramic, and/or plastic and may be a metal substrate which is made of stainless steel, and/or the like. The buffer layer 111 may have a single layer which is made of silicon nitride (SiNx) or a double layer which is made of silicon nitride (SiNx) and silicon oxide SiO₂. The buffer layer 111 serves to planarize a surface while preventing or reducing a permeation of impurity through the substrate 110.

A semiconductor layer 112 is formed on the buffer layer 111. The semiconductor layer 112 may be made of polysilicon or oxide semiconductor. The semiconductor layer 112 which is made of oxide semiconductor may be covered with a separate passivation layer. In some embodiments, the semiconductor layer 112 includes a channel region which is not doped with impurity and a source region and a drain region which are doped with impurity.

A gate insulating layer 114 is formed on the semiconductor layer 112. The gate insulating layer 114 may be formed of a single layer of silicon nitride (SiNx) or silicon oxide SiO₂ or stacked layers thereof. A gate electrode 115 and a first storage capacitor layer 113 are formed on the gate insulating layer 114. The gate electrode 115 overlaps the channel region of the semiconductor layer 112 and may include Au, Ag, Cu, Ni, Pt, Pd, Al, Mo, and/or the like.

An interlayer insulating layer 117 is formed on the gate electrode 115 and the first storage capacitor layer 113. The interlayer insulating layer 117 may be formed of a single layer of silicon nitride or silicon oxide or stacked layers thereof. A source electrode 118, a drain electrode 119, and a second storage capacitor layer 116 are formed on the interlayer insulating layer 117. The source electrode 118 and the drain electrode 119 are respectively connected to the source region and the drain region of the semiconductor layer 112 through the via holes which are formed on the interlayer insulating layer 117 and the gate insulating layer 114. The source electrode 118 and the drain electrode 119 may be formed of a multi-layered metal layer such as Mo/Al/Mo and Ti/Al/Ti.

The second storage capacitor layer 116 overlaps the first storage capacitor layer 113. Therefore, the first and second storage capacitor layers 113 and 116 form the storage capacitor Cst using the interlayer insulating layer 117 as a dielectric material.

FIG. 1 illustrates, for example, the driving thin film transistor T2 of a top gate type, but the structure of the driving thin film transistor T2 is not limited to the illustrated example. The driving thin film transistor T2 is protected by being covered with a planarization layer 105 and is electrically connected to the organic light emitting diode (OLED) to drive the organic light emitting diode (OLED).

The planarization layer 105 may be formed of a single layer of an inorganic insulator or an organic insulator or stacked layers thereof. The inorganic insulator may include SiO₂, SiNx, Al₂O₃, TiO₂, ZrO₂, and/or the like and the organic insulator may include acryl-based polymer, imide-based polymer, polystyrene, and/or the like.

A pixel electrode 151 is formed on the planarization layer 105. The pixel electrode 151 is formed in each pixel one by one and is connected to the drain electrode 119 of the driving thin film transistor T2 via the via holes which are formed on the planarization layer 105. A pixel definition layer (or barrier rib) 106 is formed on the planarization layer 105 and an edge of the pixel electrode 151. The pixel definition layer 106 may include polyacryl-based or polyimide-based resin, silica-based inorganic materials, and/or the like.

The emission layer 152 is formed on the pixel electrode 151 and the common electrode 153 is formed on the emission layer 152 and the pixel definition layer 106. The common electrode 153 is formed in the whole display area without being differentiated for each pixel. Any one of the pixel electrode 151 and the common electrode 153 serves as an anode which injects holes into the emission layer 152 and the other thereof serves as a cathode which injects electrons into the emission layer 152.

The emission layer 152 includes an organic emission layer and includes at least one of a hole injection layer, a hole transportation layer, an electron transportation layer, and an electron injection layer. When the pixel electrode 151 is an anode and the common electrode 153 is a cathode, a hole injection layer, a hole transportation layer, an organic emission layer, an electron transportation layer, and an electron injection layer may be sequentially stacked over the pixel electrode 151.

The electrons and the holes are combined in the organic emission layer to generate excitons, and light is emitted by energy generated when the excitons drop from an excited state to a ground state. In some embodiments, the pixel electrode 151 is formed of a reflective layer and the common electrode 153 is formed of a transparent layer or a translucent layer. As a result, light emitted from the emission layer 152 is reflected from the pixel electrode 151 and transmits the common electrode 153 to be emitted to the outside.

The reflecting layer may include Au, Ag, Mg, Al, Pt, Pd, Ni, Nd, Ir, Cr, and/or the like. The transparent layer may include indium tin oxide (ITO), indium zinc oxide (IZO), zinc oxide (ZnO), indium oxide (In₂O₃), and/or the like. The translucent layer may be formed of a metal thin film including Li, Ca, LiF/Ca, LiF/Al, Al, Ag, Mg, and/or the like and the transparent layer of ITO, IZO, ZnO, In₂O₃, and/or the like may be formed on the translucent layer.

The plurality of pixels PX1, PX2, and PX3 which are formed on the substrate 110 includes a red pixel PX1, a green pixel PX2, and a blue pixel PX3. The red pixel PX1, the green pixel PX2, and the blue pixel PX3 respectively include a red emission layer, a green emission layer, and a blue emission layer. The organic light emitting diode display 100 may implement a full-color image by a combination of three colors.

The encapsulation substrate 120 is bonded to the substrate 110 by a sealant and encapsulates the plurality of pixels PX1, PX2, and PX3 to block an infiltration of external air. The encapsulation substrate 120 may be made of transparent insulating materials such as glass and/or quartz. The color filter 130 is formed on one surface of the encapsulation substrate 120 toward (e.g., facing) the plurality of pixels PX1, PX2, and PX3. The color filter 130 includes a red filter 130R, a green filter 130G, and a blue filter 1308 which correspond to a red pixel PX1, a green pixel PX2, and a blue pixel PX3, respectively.

The color filter 130 absorbs light in the remaining wavelength bands other than a wavelength band of color of the external light (visible light wavelength) incident on the organic light emitting diode display 100. Therefore, light having a specific color which is emitted from the organic light emitting diode (OLED) is not mixed with external light in other wavelength bands, and the organic light emitting diode display 100 may use the color filter 130 to suppress the external light reflection. The color filter 130 may include acrylic resin, polyimide-based resin, and/or the like.

A black layer (or black matrix layer) 135 may be formed among the red filter 130R, the green filter 130G, and the blue filter 130B. The black layer 135 may include a metal layer made of chromium (Cr), and/or the like, metal compounds such as chromium oxide (CrOx) and chromium nitride (CrNx), or organic matters such as carbon black, a pigment mixture, and/or a dye mixture.

The color filter 130 and the black layer 135 are covered with the overcoat layer 140. The overcoat layer 140 protects the color filter 130 to increase reliability of the color filter 130 and reduces or minimizes a transmittance loss due to the color filter 130, and thus serves to increase light efficiency. The overcoat layer 140 includes a first region 141 covering the red filter 130R, a second region 142 covering the green filter 130G, and a third region 143 covering the blue filter 130B.

If it is assumed that there is no overcoat layer 140, the color filter 130 contacts an air layer 125 between the substrate 110 and the encapsulation substrate 120. In this case, some of the light emitted from the organic light emitting diode (OLED) would be reflected from the surface of the color filter 130 due to a difference between a refractive index of air and a refractive index of the color filter 130. Therefore, the transmittance loss would occur due to the color filter 130, which leads to a deterioration in light efficiency.

The overcoat layer 140 has a refractive index which is larger than that of air and is smaller than that of the color filter 130. The refractive index of air is 1 and the refractive index of the color filter 130 made of the acrylic resin or the polyimide-based resin is between about 1.5 and 1.8. The overcoat layer 140 may have a refractive index of about 1.2 to 1.3 and may be made of acrylic resin which includes LiF. In the acrylic resin including the LiF, the refractive index may be changed depending on a content of fluorine (F).

The overcoat layer 140 makes the change in the refractive index smooth when the light emitted from the organic light emitting diode (OLED) is incident on the color filter 130 to reduce or minimize the amount of light reflected from the surface of the color filter 130. Further, any one of the first region 141, the second region 142, and the third region 143 optimizes the refractive index and the thickness to improve or maximize the light efficiency. Herein, the optimization means a design to reduce or minimize the light reflection from the surface of the color filter 130 in consideration of a peak wavelength of the corresponding pixel and the refractive index of the corresponding color filter 130.

In the organic light emitting diode display 100 according to the first exemplary embodiment, any one of the first region 141, the second region 142, and the third region 143 is formed to satisfy at least one of the following Equations 1 and 2.

$$\begin{matrix}OC ( n ) = \sqrt{CF ( n ) \times AIR ( n )} & Equation 1 \\ OC ( d ) = \frac{λ}{4 \sqrt{CF ( n ) \times AIR ( n )}} & Equation 2\end{matrix}$$

In the above Equations 1 and 2, OC(n) represents the refractive index of the corresponding region and OC(d) represents the thickness of the corresponding region. CF(n) represents the refractive index of the corresponding color filter, AIR(n) represents the refractive index of air, and A represents a peak wavelength of the corresponding pixel. The above Equation 2 may be represented by the following Equation 3.

$$OC ( d ) = \frac{λ}{4 OC ( n )} \qquad Equation 3$$

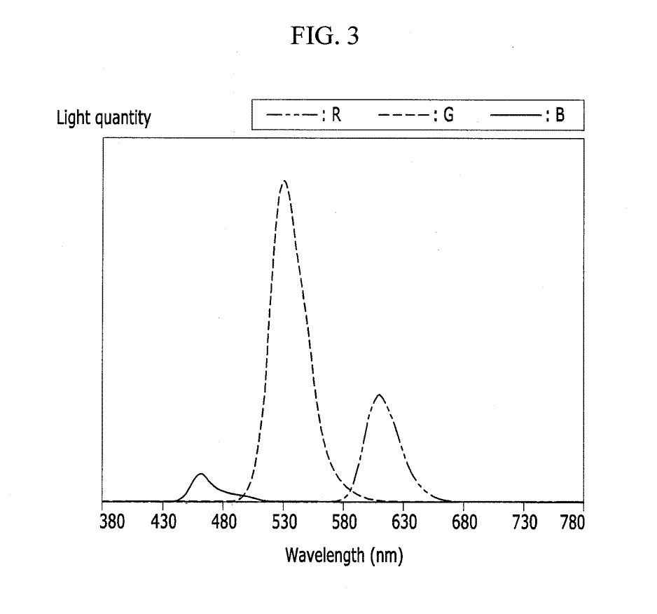

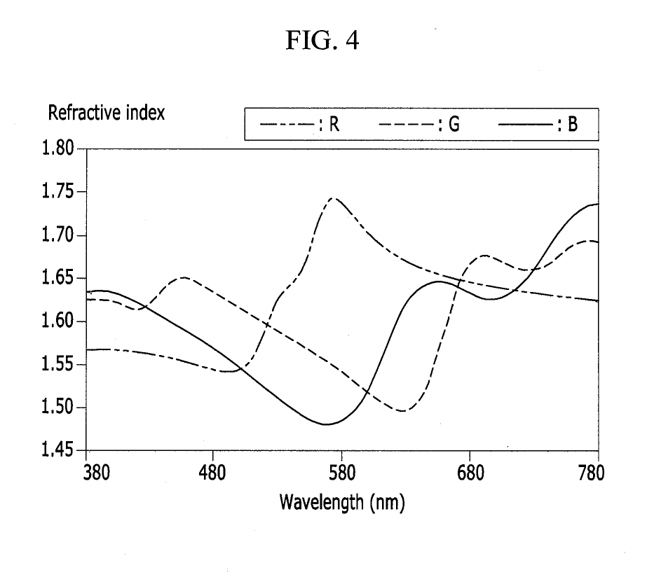

FIG. 3 is a graph illustrating emission spectra of a red pixel, a green pixel, and a blue pixel in the organic light emitting diode display illustrated in FIG. 1, and FIG. 4 is a graph illustrating refractive indexes depending on wavelengths of a red filter, a green filter, and a blue filter in the organic light emitting diode display illustrated in FIG. 1.

Referring to FIG. 3, a peak wavelength of red light R which is emitted by the red pixel is about 610 nm, a peak wavelength of green light G which is emitted by the green pixel is about 540 nm, and a peak wavelength of blue light B which is emitted by the blue pixel is about 460 nm.

Referring to FIG. 4, the refractive index of the red filter which is measured in the peak wavelength (about 610 nm) of the red light is about 1.69, the refractive index of the green filter which is measured in the peak wavelength (about 540 nm) of the green light is about 1.57, and the refractive index of the blue filter which is measured in the peak wavelength (about 460 nm) of the blue light is about 1.58.

Referring to FIG. 1, in the above Equation 1, the CF(n) is about 1.69 in the case of the red filter 130R, about 1.57 in the case of the green filter 130G, and about 1.58 in the case of the blue filter 130B. The above Equation 1 optimizes the refractive index of the overcoat layer 140 in consideration of the refractive index of the corresponding color filter 130 and the above Equation 2 optimizes the thickness of the overcoat layer 140 in consideration of the peak wavelength of the corresponding pixel and the refractive index of the corresponding color filter 130.

Any one of the first region 141, the second region 142, and the third region 143, for example the third region, 143 is formed to satisfy the above Equations 1 and 2 to optimize both of the refractive index and the thickness. Further, the remaining two of the regions, that is, the first region 141 and the second region 142, are made of the same or substantially the same material (refractive index) as the third region 143 and are formed to have the same or substantially the same thickness as the third region 143.

The pixel to which the optimization design is applied is not limited to the blue pixel PX3 and therefore other pixels may be selected depending on material efficiency, white color coordinates, and/or the like. The organic light emitting diode display 100 according to the first exemplary embodiment may use the overcoat layer 140 to reduce the light reflection of the color filter 130 and may optimize the refractive index and the thickness of the overcoat layer 140 in the specific pixel to improve or maximize the light efficiency.

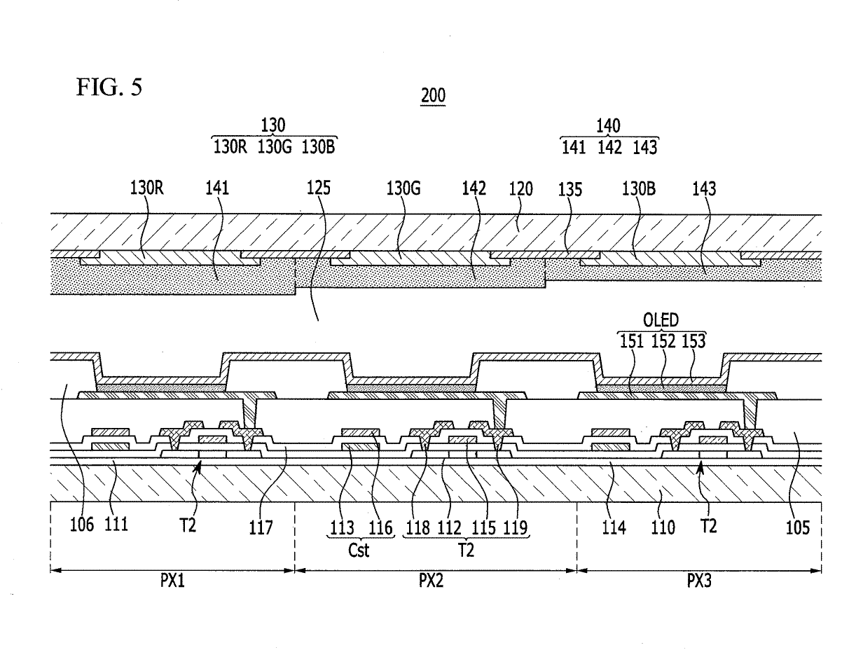

FIG. 5 is a cross-sectional view of an organic light emitting diode display according to a second exemplary embodiment.

Referring to FIG. 5, in an organic light emitting diode display 200 according to a second exemplary embodiment, any one of the first region 141, the second region 142, and the third region 143 of the overcoat layer 140 is formed to satisfy the above Equation 1 and all of the first region 141, the second region 142, and the third region 143 are formed to satisfy the above Equation 2.

Any one of the first region 141, the second region 142, and the third region 143, for example the third region 143, is formed to satisfy the above Equation 1 to have the optimized refractive index. The remaining two of the regions, that is, the first region 141 and the second region 142, are made of the same or substantially the same material (refractive index) as the third region 143. Further, all of the first region 141, the second region 142, and the third region 143 are formed to satisfy the above Equation 2 to have the optimized thickness.

As compared with the first exemplary embodiment, the organic light emitting diode display 200 according to the second exemplary embodiment may increase the light efficiency by optimizing or improving the thickness of all of the first region 141, the second region 142, and the third region 143. The remaining configuration other than the overcoat layer 140 is the same or substantially the same as the foregoing first exemplary embodiment.

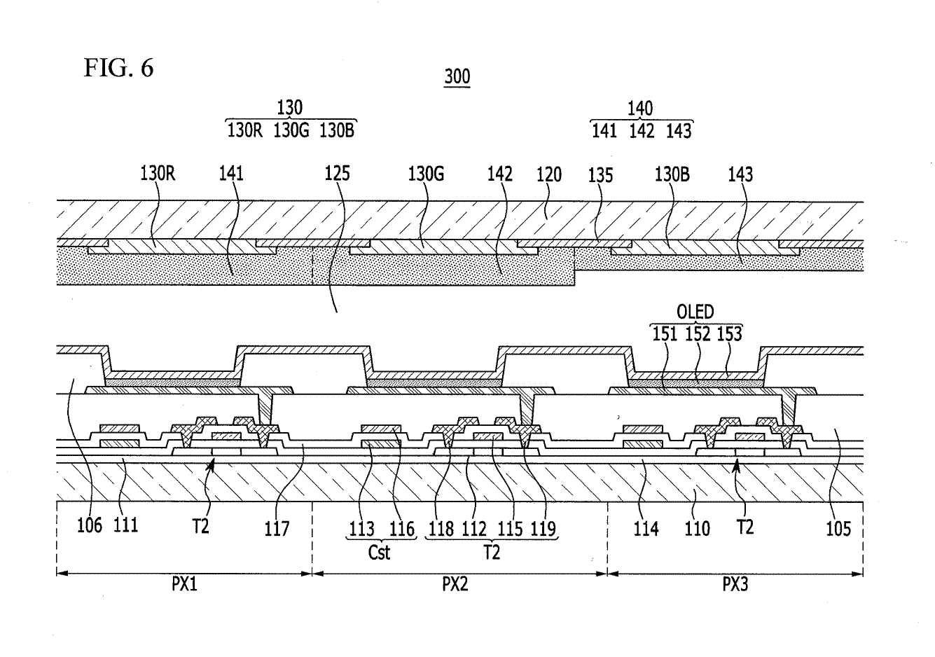

FIG. 6 is a cross-sectional view of an organic light emitting diode display according to a third exemplary embodiment.

Referring to FIG. 6, in an organic light emitting diode display 300 according to a third exemplary embodiment, any one of the first region 141, the second region 142, and the third region 143 of the overcoat layer 140 is formed to satisfy the above Equation 1 and two of the first region 141, the second region 142, and the third region 143 are formed to satisfy the above Equation 2.

Any one of the first region 141, the second region 142, and the third region 143, for example the third region 143, is formed to satisfy the above Equation 1 to have the optimized refractive index. The remaining two of the regions, that is, the first region 141 and the second region 142, are made of the same or substantially the same material (refractive index) as the third region 143.

Further, two of the first region 141, the second region 142, and the third region 143, for example, the first region 141 and the third region 143, are formed to satisfy the above Equation 2 to have the optimized thickness. The second region 142 is formed to have the same or substantially the same thickness as the first region 141 or the third region 143. FIG. 6 illustrates, for example, the case in which the thickness of the second region 142 is the same or substantially the same as the thickness of the first region 141.

As compared with the second exemplary embodiment, with regards to the organic light emitting diode display 300 according to the third exemplary embodiment, it may be easier to manufacture the overcoat layer 140 when forming the two regions at the same or substantially the same thickness. The remaining configuration other than the overcoat layer 140 is the same or substantially the same as the foregoing first exemplary embodiment.

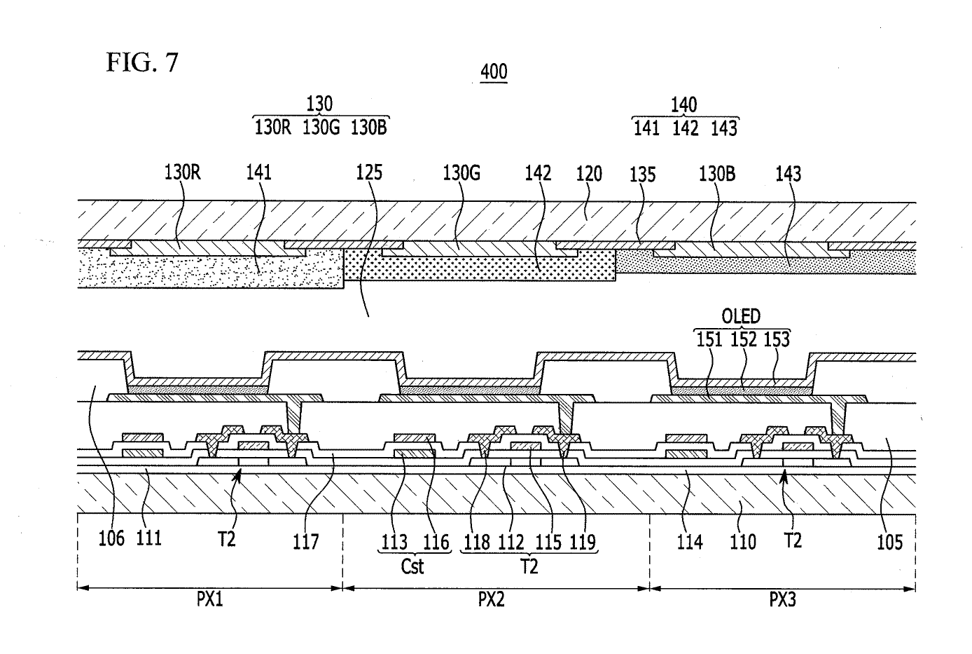

FIG. 7 is a cross-sectional view of an organic light emitting diode display according to a fourth exemplary embodiment.

Referring to FIG. 7, in an organic light emitting diode display 400 according to a fourth exemplary embodiment, all of the first region 141, the second region 142, and the third region 143 are formed to satisfy the above Equations 1 and 2.

All of the first region 141, the second region 142, and the third region 143 are formed to satisfy the above Equation 1 to have the optimized refractive index. Further, all of the first region 141, the second region 142, and the third region 143 are formed to satisfy the above Equation 2 to have the optimized thickness.

As compared with the first to third exemplary embodiments, the organic light emitting diode display 400 according to the fourth exemplary embodiment may improve the light efficiency by optimizing the refractive index and the thickness of the overcoat layer 140 in all of the red pixel PX1, the green pixel PX2, and the blue pixel PX3. The remaining configuration other than the overcoat layer 140 is the same or substantially the same as the foregoing first exemplary embodiment.

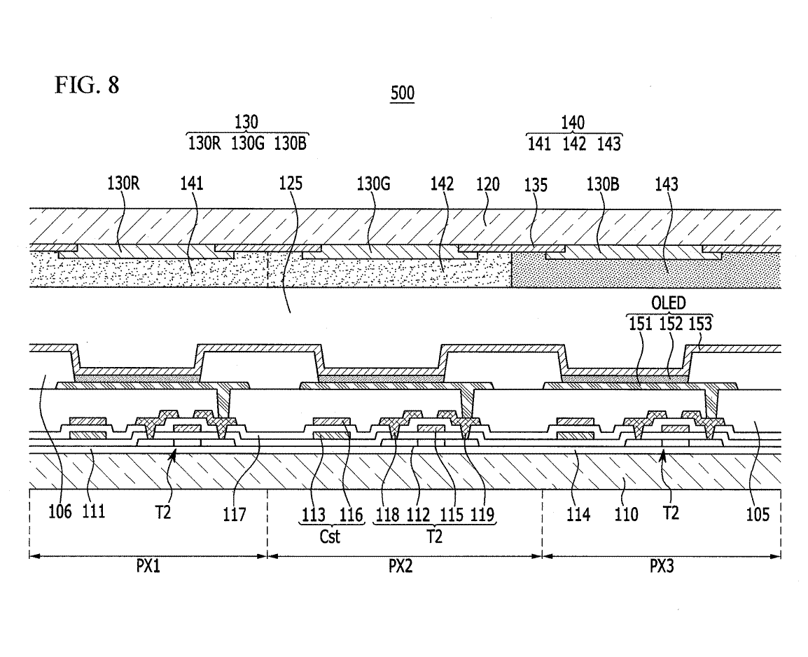

FIG. 8 is a cross-sectional view of an organic light emitting diode display according to a fifth exemplary embodiment.

Referring to FIG. 8, in an organic light emitting diode display 500 according to a fifth exemplary embodiment, two of the first region 141, the second region 142, and the third region 143 are formed to satisfy the above Equation 1 and any one of the first region 141, the second region 142, and the third region 143 are formed to satisfy the above Equation 2.

Two of the first region 141, the second region 142, and the third region 143, for example the first region 141 and the third region 143, are formed to satisfy the above Equation 1 to have the optimized refractive index. The second region 142 may be made of the same or substantially the same material (refractive index) as the first region 141 or the third region 143. FIG. 8 illustrates, for example, the case in which the second region 142 is made of the same or substantially the same material as the first region 141.

Further, any one of the first region 141, the second region 142, and the third region 143, for example, the first region 141, is formed to satisfy the above Equation 2 to have the optimized thickness. The remaining two of the regions other than the first region 141, that is, the second region 142 and the third region 143, are formed to have the same or substantially the same thickness as the first region 141.

As compared with the fourth exemplary embodiment, with regards to the organic light emitting diode display 500 according to the fifth exemplary embodiment, it may be easier to manufacture the overcoat layer 140 when one of the construction materials of the overcoat layer 140 is removed and there is no difference in the thickness of the overcoat layer 140. The remaining configuration other than the overcoat layer 140 is the same or substantially the same as the foregoing first exemplary embodiment.

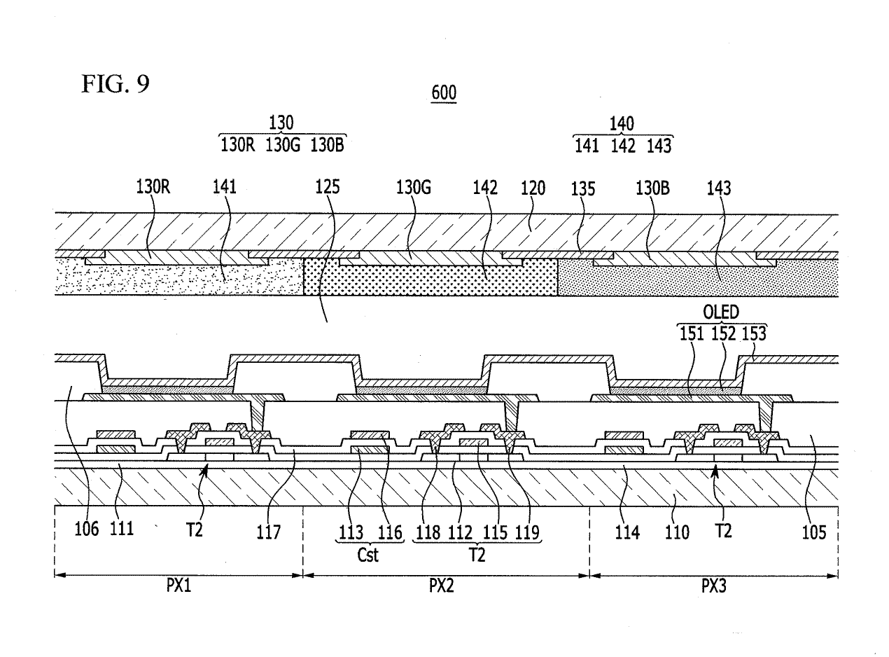

FIG. 9 is a cross-sectional view of an organic light emitting diode display according to a sixth exemplary embodiment.

Referring to FIG. 9, in an organic light emitting diode display 600 according to a sixth exemplary embodiment, all of the first region 141, the second region 142, and the third region 143 are formed to satisfy the above Equation 1 and any one of the first region 141, the second region 142, and the third region 143 is formed to satisfy the above Equation 2.

All of the first region 141, the second region 142, and the third region 143 are formed to satisfy the above Equation 1 to have the optimized refractive index. Further, any one of the first region 141, the second region 142, and the third region 143, for example the first region 141, is formed to satisfy the above Equation 2 to have the optimized thickness. The remaining two of the regions other than the first region 141, that is, the second region 142 and the third region 143, are formed to have the same or substantially the same thickness as the first region 141.

As compared with the fourth exemplary embodiment, with regards to the organic light emitting diode display 600 according to the sixth exemplary embodiment, it may be easier to manufacture the overcoat layer 140 when there is no difference in the thickness of the overcoat layer 140. The remaining configuration other than the overcoat layer 140 is the same or substantially the same as the foregoing first exemplary embodiment.

Next, the light efficiency between an organic light emitting diode display according to Comparative Example in which the overcoat layer is omitted and the organic light emitting diode display according to the first exemplary embodiment (Experimental Examples 1, 2, 3) and the fourth exemplary embodiment (Experimental Example 4) of the present disclosure will be compared and described with reference to the following Table 1. In the organic light emitting diode display according to Comparative Example, the color filter directly contacts the air layer.

Experimental Example 1 is the case in which the refractive index and the thickness of the first region are optimized, and Experimental Example 2 is the case in which the refractive index and the thickness of the second region are optimized. Experimental Example 3 is the case in which the refractive index and the thickness of the third region are optimized and Experimental Example 4 is the case in which the refractive index and the thickness in all of the first region, the second region, and the third region are optimized.

TABLE 1

| | White light | Red light | Green light | Blue light |
|---|---|---|---|---|
| | efficiency | efficiency | efficiency | efficiency |
| Comparative | 25.3 | 46.5 | 91.6 | 5.53 |
| Example | | | | |
| Experimental | 27.5 (108.6%) | 49.8 | 92.6 | 5.73 |
| Example 1 | | | | |
| Experimental | 27.7 (109.6%) | 52.2 | 93.3 | 5.75 |
| Example 2 | | | | |
| Experimental | 27.9 (110.4%) | 52.0 | 93.7 | 5.78 |
| Example 3 | | | | |
| Experimental | 29.1 (115.1%) | 53.3 | 102.6 | 5.78 |
| Example 4 | | | | |

It may be appreciated from the results shown in Table 1 that Experimental Example 3 shows light efficiency higher than that of Experimental Examples 1 and 2, and Experimental Example 4 shows light efficiency higher than that of Experimental Example 3. In the case of Experimental Example 3, the light efficiency was 10% higher than that of Comparative Example and in the case of Experimental Example 4, the light efficiency was 15% higher than Comparative Example.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and their equivalents.

Description of Some of the Reference Charaters:

100, 200, 300, 400, 500, 600: Organic light emitting diode display

| | |
|---|---|
| 110: Substrate | 120: Encapsulation substrate |
| 130: Color filter | 130R: Red filter |
| 130G: Green filter | 130B: Blue filter |
| 135: Black layer | 140: Overcoat layer |
| 141: First region | 142: Second region |

143: Third region

What is claimed is:

1. An organic light emitting diode display comprising:
a plurality of pixels on a substrate;
an encapsulation substrate facing the substrate;
a color filter on one surface of the encapsulation substrate and comprising a red filter, a green filter, and a blue filter; and
an overcoat layer comprising a first region covering the red filter, a second region covering the green filter, and a third region covering the blue filter, the overcoat layer contacting the red filter, the green filter and the blue filter,
wherein at least one of the first region, the second region, and the third region satisfies at least one of the following Condition 1 and Condition 2:
$$\begin{matrix}OC ( n ) = \sqrt{CF ( n ) \times AIR ( n )} & Condition 1 \\ OC ( d ) = \frac{λ}{4 \sqrt{CF ( n ) \times AIR ( n )}} , & Condition 2\end{matrix}$$
and
wherein in the above Conditions 1 and 2, OC(n) represents a refractive index of a corresponding region, CF(n) represents a refractive index of a corresponding color filter, AIR(n) represents a refractive index of air, OC(d) represents a thickness of the corresponding region, and λ represents a peak wavelength of a corresponding pixel, and
wherein all of the first region, the second region, and the third region have the same thickness as each other.

2. The organic light emitting diode display of claim 1,
wherein the plurality of pixels comprises a red pixel, a green pixel, and a blue pixel, and
wherein the red filter, the green filter, and the blue filter are respectively positioned to correspond to the red pixel, the green pixel, and the blue pixel.

3. The organic light emitting diode display of claim 2,
wherein the red pixel, the green pixel, and the blue pixel have peak wavelengths of λ1, λ2, and λ3, respectively, and
wherein the refractive index CF(n) of the color filter is any one of the refractive index of the red filter which is measured in the wavelength of λ1, the refractive index of the green filter which is measured in the wavelength of λ2, and the refractive index of the blue filter which is measured in the wavelength of λ3.

4. The organic light emitting diode display of claim 1,
wherein the refractive index of the overcoat layer is larger than that of air and is smaller than that of the color filter.

5. The organic light emitting diode display of claim 4,
wherein the refractive index of the overcoat layer is between 1.2 and 1.3 and is made of acrylic resin which comprises LiF.

6. The organic light emitting diode display of claim 1,
wherein any one of the first region, the second region, and the third region satisfies the above Conditions 1 and 2.

7. An organic light emitting diode display comprising:
a plurality of pixels on a substrate;
an encapsulation substrate facing the substrate;
a color filter on one surface of the encapsulation substrate and comprising a red filter, a green filter, and a blue filter; and
an overcoat layer comprising a first region covering the red filter, a second region covering the green filter, and a third region covering the blue filter, the overcoat layer contacting the red filter, the green filter, and the blue filter,
wherein at least one of the first region, the second region, and the third region satisfies at least one of the following Condition 1 and Condition 2:
$$\begin{matrix}OC ( n ) = \sqrt{CF ( n ) \times AIR ( n )} & Condition 1 \\ OC ( d ) = \frac{λ}{4 \sqrt{CF ( n ) \times AIR ( n )}} , & Condition 2\end{matrix}$$
and
wherein in the above Conditions 1 and 2, OC(n) represents a refractive index of a corresponding region, CF(n) represents a refractive index of a corresponding color filter, AIR(n) represents a refractive index of air, OC(d) represents a thickness of the corresponding region, and λ represents a peak wavelength of a corresponding pixel,
wherein any one of the first region, the second region, and the third region satisfies the above Condition 1 and the remaining two of the regions are made of the same material as any one of the above regions, and
wherein two of the first region, the second region, and the third region satisfy the above Condition 2 and the remaining one of the regions has the same thickness as any one of the two regions.

8. The organic light emitting diode display of claim 7,
wherein two regions of the first region, the second region, and the third region satisfy the above Condition 1 and the remaining one of the regions is made of the same material as any one of the two regions, and
wherein any one of the first region, the second region, and the third region satisfies the above Condition 2.

9. The organic light emitting diode display of claim 7,
wherein all of the first region, the second region, and the third region satisfy the above Condition 1, and
wherein any one of the first region, the second region, and the third region satisfies the above Condition 2.
